(19) United States
(12) Patent Application Publication
(10) Pub. No.: US 2024/0392189 A1
(43) Pub. Date: Nov. 28, 2024

(54) PHOSPHOR, WAVELENGTH CONVERSION DEVICE, ILLUMINATION DEVICE, AND PROJECTOR

(71) Applicant: SEIKO EPSON CORPORATION, Tokyo (JP)

(72) Inventors: Kengo KANO, MATSUMOTO-SHI (JP); Soma TODA, MATSUMOTO-SHI (JP)

(21) Appl. No.: 18/673,606

(22) Filed: May 24, 2024

(30) Foreign Application Priority Data
May 24, 2023 (JP) 2023-085215

(51) Int. Cl. C09K 11/77; C09K 11/02; G03B 21/20

(52) U.S. Cl. CPC C09K 11/7701; C09K 11/025; G03B 21/204; G03B 21/2066

(57) ABSTRACT

A phosphor includes a phosphor body including a phosphor phase formed of A₃B₅O₁₂:Ce having a garnet structure, a matrix phase having a refractive index higher than a refractive index of the phosphor phase, and an oxide layer provided between the phosphor phase and the matrix phase. The oxide layer includes a composite oxide of a metal contained in the phosphor phase and a metal contained in the sintering additive. A content of the oxide layer is equal to or more than 0.1 vol % and is equal to or less than 0.9 vol % in a volume ratio with respect to the phosphor body. A is at least one selected from a group including Lu, Gd, Tb, Ga, and Y, and B is Al.

The present application is based on, and claims priority from JP Application Serial Number 2023-085215, filed May 24, 2023, the disclosure of which is hereby incorporated by reference herein in its entirety.

### BACKGROUND

### 1. Technical Field

The present disclosure relates to a phosphor, a wavelength conversion device, an illumination device, and a projector.

### 2. Related Art

In the related art, a ceramic composite is used as a wavelength conversion member used in a light source for a projector. JP-A-2012-062459 discloses a ceramic composite including an inorganic material having a matrix phase formed of a transparent ceramic such as Al₂O₃, MgAl₂O₄, or MgO, and a phosphor phase formed of YAG containing Ce.

However, in the ceramic composite disclosed in JP-A-2012-062459, although a thermal conductivity is improved by mixing and sintering of a high thermal conductive filler, it is difficult to sufficiently improve fluorescence extraction efficiency.

### SUMMARY

In order to solve the above problems, according to an aspect of the present disclosure, there is provided a phosphor including a phosphor body including a phosphor phase formed of A₃B₅O₁₂:Ce having a garnet structure, a matrix phase having a refractive index higher than a refractive index of the phosphor phase, and an oxide layer provided between the phosphor phase and the matrix phase. The oxide layer is made of a composite oxide of a metal contained in the phosphor phase and a metal contained in the sintering additive. A content of the oxide layer is equal to or more than 0.1 vol % and is equal to or less than 0.9 vol % in a volume ratio with respect to the phosphor body. A is at least one selected from a group including Lu, Gd, Tb, Ga, and Y, and B is Al.

According to another aspect of the present disclosure, there is provided a wavelength conversion device including a substrate, the phosphor according to the above aspect, provided on the substrate and configured to convert an incident excitation light into fluorescence, and a reflection layer provided at an opposite side to a light incident side of the phosphor and configured to reflect the excitation light and the fluorescence.

According to still another aspect of the present disclosure, there is provided a wavelength conversion device including a substrate, the phosphor according to the above aspect, provided on the substrate and configured to convert an incident excitation light into fluorescence, and an optical layer provided on a light incident side of the phosphor and configured to transmit the excitation light and reflect the fluorescence.

According to another aspect of the present disclosure, there is provided an illumination device including a light source emitting an excitation light, and the wavelength conversion device according to the above aspect on which the excitation light is incident.

According to yet another aspect of the present disclosure, there is provided a projector including the illumination device according to the above aspect, a light modulator modulating a light emitted from the illumination device, and a projection optical device projecting the light modulated by the light modulator.

### BRIEF DESCRIPTION OF THE DRAWINGS

FIG. 1 is a schematic configuration diagram showing a projector according to a first embodiment.

FIG. 2 is a schematic configuration diagram showing an illumination device.

FIG. 3 is a cross-sectional view showing a configuration of a wavelength conversion device.

FIG. 4 is an SEM image of a phosphor.

FIG. 5 is a schematic configuration diagram showing an illumination device according to a second embodiment.

### DESCRIPTION OF EMBODIMENTS

As below, embodiments of the present disclosure will be described in detail with reference to the drawings. In the drawings used in the following description, in order to facilitate understanding of features, a feature portion may be shown in an enlarged manner for convenience, and dimensional ratios or the like of the respective component elements are not necessarily the same as actual dimensional ratios.

### First Embodiment

Hereinafter, an embodiment of the present disclosure will be described.

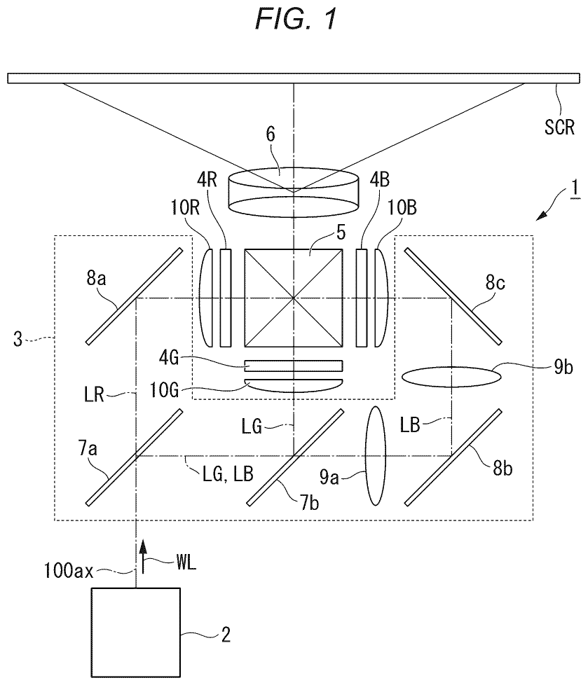

FIG. 1 is a schematic configuration diagram showing a projector according to a first embodiment.

As shown in FIG. 1, a projector 1 according to the embodiment is a projection-type image display device that displays an image on a screen SCR. The projector 1 includes an illumination device 2, a color separation system 3, a light modulator 4R, a light modulator 4G, a light modulator 4B, a combining system 5, and a projection optical device 6.

The illumination device 2 emits a white illumination light WL toward the color separation system 3. A configuration of the illumination device 2 will be described in detail later.

The color separation system 3 separates the illumination light WL emitted from the illumination device 2 into a red light LR, a green light LG, and a blue light LB. The color separation system 3 includes a first dichroic mirror 7a, a second dichroic mirror 7b, a first reflection mirror 8a, a second reflection mirror 8b, a third reflection mirror 8c, a first relay lens 9a, and a second relay lens 9b.

The first dichroic mirror 7a separates the illumination light WL from the illumination device 2 into the red light LR and a light including the green light LG and the blue light LB. The first dichroic mirror 7a transmits the red light LR and reflects the light including the green light LG and the blue light LB. On the other hand, the second dichroic mirror 7b reflects the green light LG and transmits the blue light LB. Accordingly, the second dichroic mirror 7b separates the light including the green light LG and the blue light LB into the green light LG and the blue light LB.

The first reflection mirror 8a is disposed in an optical path of the red light LR, and reflects the red light LR transmitted through the first dichroic mirror 7a toward the light modulator 4R. On the other hand, the second reflection mirror 8b and the third reflection mirror 8c are disposed in an optical path of the blue light LB, and guide the blue light LB transmitted through the second dichroic mirror 7b to the light modulator 4B. The green light LG is reflected from the second dichroic mirror 7b toward the light modulator 4G.

The first relay lens 9a is disposed between the second dichroic mirror 7b and the second reflection mirror 8b in the optical path of the blue light LB. The second relay lens 9b is disposed between the second reflection mirror 8b and the third reflection mirror 8c in the optical path of the blue light LB. The first relay lens 9a and the second relay lens 9b compensate for an optical loss of the blue light LB due to an optical path length of the blue light LB being longer than an optical path length of the red light LR or the green light LG.

The light modulator 4R modulates the red light LR according to image information to form an image light corresponding to the red light LR. The light modulator 4G modulates the green light LG according to image information to form an image light corresponding to the green light LG. The light modulator 4B modulates the blue light LB according to image information to form an image light corresponding to the blue light LB.

For example, a transmissive liquid crystal panel is used for each of the light modulator 4R, the light modulator 4G, and the light modulator 4B. A polarizer (not shown) is disposed at each of a light incident side and a light exiting side of the liquid crystal panel.

A field lens 10R is disposed at a light incident side of the light modulator 4R. The field lens 10R parallelizes the red light LR incident on the light modulator 4R. A field lens 10G is disposed at a light incident side of the light modulator 4G. The field lens 10G parallelizes the green light LG incident on the light modulator 4G. A field lens 10B is disposed at a light incident side of the light modulator 4B. The field lens 10B parallelizes the blue light LB incident on the light modulator 4B.

The image lights emitted from the light modulator 4R, the light modulator 4G, and the light modulator 4B enter the combining system 5. The combining system 5 combines the image lights respectively corresponding to the red light LR, the green light LG, and the blue light LB, and emits the combined image light toward the projection optical device 6. For example, a cross dichroic prism is used for the combining system 5.

The projection optical device 6 includes a plurality of projection lenses. The projection optical device 6 enlarges and projects the image light combined by the combining system 5 toward the screen SCR. Accordingly, an enlarged image is displayed on the screen SCR.

Hereinafter, a configuration of the illumination device 2 will be described.

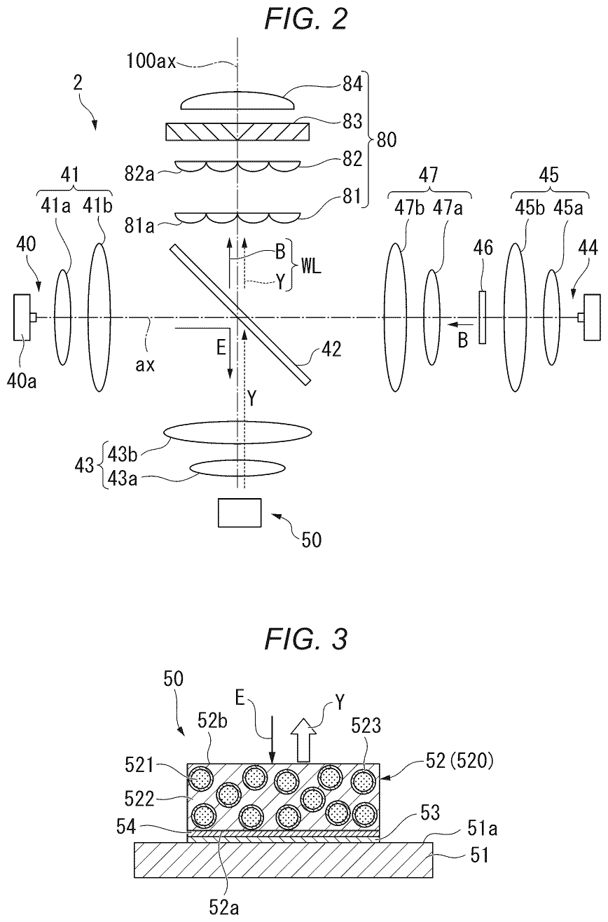

FIG. 2 is a schematic configuration diagram showing the illumination device 2 according to the embodiment.

As shown in FIG. 2, the illumination device 2 includes a first light source 40, a collimating system 41, a dichroic mirror 42, a first condensing system 43, a wavelength conversion device 50, a second light source 44, a second condensing system 45, a diffuser 46, and a collimating system 47.

The first light source 40 includes a plurality of semiconductor lasers 40a that emit a blue excitation light E of a laser beam. A peak of an emission intensity of the excitation light E is, for example, 445 nm. The plurality of semiconductor lasers 40a are arranged in an array manner in one plane orthogonal to an optical axis ax of the first light source 40. The semiconductor laser 40a may be a semiconductor laser that emits a blue light having a wavelength other than 445 nm, for example, 455 nm or 460 nm. The optical axis ax of the first light source 40 is orthogonal to an illumination optical axis 100ax of the illumination device 2.

The first light source 40 according to the embodiment corresponds to “light source” in the claims.

The collimating system 41 includes a first lens 41a and a second lens 41b. The collimating system 41 substantially parallelizes the light emitted from the first light source 40. Each of the first lens 41a and the second lens 41b is formed using a convex lens.

The dichroic mirror 42 is disposed in an optical path from the collimating system 41 to the first condensing system 43 in a direction intersecting each of the optical axis ax of the first light source 40 and the illumination optical axis 100ax at an angle of 45°. The dichroic mirror 42 reflects a blue light component and transmits a red light component and a green light component. Therefore, the dichroic mirror 42 reflects the excitation light E and the blue light B and transmits yellow fluorescence Y.

The first condensing system 43 condenses the excitation light E transmitted through the dichroic mirror 42 and causes the excitation light E to enter the wavelength conversion device 50, and substantially parallelizes the fluorescence Y emitted from the wavelength conversion device 50. The first condensing system 43 includes a first lens 43a and a second lens 43b. Each of the first lens 43a and the second lens 43b is formed using a convex lens.

The second light source 44 is formed using a semiconductor laser having a wavelength band same as a wavelength band of the first light source 40. The second light source 44 may be formed using one semiconductor laser, or may be formed using a plurality of semiconductor lasers. In addition, the second light source 44 may be formed using a semiconductor laser having a wavelength band different from that of the semiconductor laser of the first light source 40.

The second condensing system 45 includes a first lens 45a and a second lens 45b. The second condensing system 45 condenses the blue light B emitted from the second light source 44 on a diffusion surface of the diffuser 46 or near the diffusion surface. Each of the first lens 45a and the second lens 45b is formed using a convex lens.

The diffuser 46 diffuses the blue light B emitted from the second light source 44, and generates the blue light B having a light distribution close to a light distribution of the fluorescence Y emitted from the wavelength conversion device 50. As the diffuser 46, for example, a ground glass of an optical glass can be used.

The collimating system 47 includes a first lens 47a and a second lens 47b. The collimating system 47 substantially parallelizes the light emitted from the diffuser 46. Each of the first lens 47a and the second lens 47b is formed using a convex lens.

The blue light B emitted from the second light source 44 is reflected by the dichroic mirror 42, and is combined with the fluorescence Y emitted from the wavelength conversion device 50 and transmitted through the dichroic mirror 42 to generate the white illumination light WL. The illumination light WL enters a uniform illumination system 80.

The uniform illumination system 80 includes a first lens array 81, a second lens array 82, a polarization conversion element 83, and a superimposing lens 84.

The first lens array 81 includes a plurality of first lenses 81a for dividing the illumination light WL from the illumination device 2 into a plurality of partial luminous fluxes. The plurality of first lenses 81a are arranged in a matrix form in a plane orthogonal to the illumination optical axis 100ax.

The second lens array 82 includes a plurality of second lenses 82a corresponding to the plurality of first lenses 81a of the first lens array 81. The plurality of second lenses 82a are arranged in a matrix form in the plane orthogonal to the illumination optical axis 100ax.

The second lens array 82, together with the superimposing lens 84, forms images of the respective first lenses 81a of the first lens array 81 in the vicinity of image formation areas of the light modulator 4R, the light modulator 4G, and the light modulator 4B.

The polarization conversion element 83 converts the light emitted from the second lens array 82 into one linearly polarized light. The polarization conversion element 83 includes, for example, a polarization separation layer and a retardation film (not shown).

The superimposing lens 84 condenses the respective partial luminous fluxes emitted from the polarization conversion element 83 and superimposes the luminous fluxes in the vicinity of the image formation areas of the light modulator 4R, the light modulator 4G, and the light modulator 4B.

Next, a configuration of the wavelength conversion device 50 will be described.

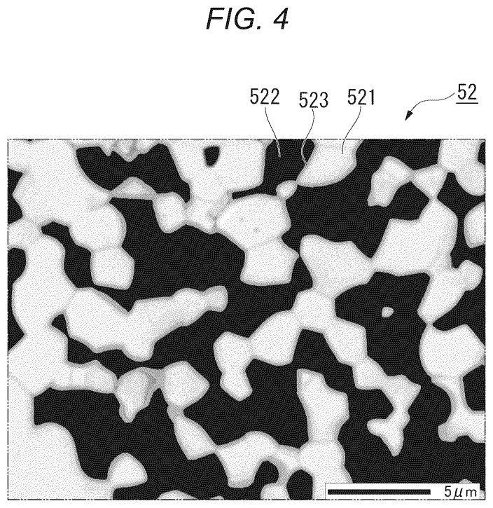

FIG. 3 is a cross-sectional view showing the configuration of the wavelength conversion device 50. FIG. 3 corresponds to a cross section of the wavelength conversion device 50 cut along a plane containing the illumination optical axis 100ax in FIG. 2.

As shown in FIG. 3, the wavelength conversion device 50 includes a substrate 51, a phosphor 52, a bonding layer 53, and a reflection layer 54. The wavelength conversion device 50 according to the embodiment is a fixed type wavelength conversion device in which an incident position of the excitation light E on the phosphor 52 does not change over time.

The substrate 51 supports the reflection layer 54 and the phosphor 52 through the bonding layer 53. The substrate 51 is formed of, for example, a metal material having a high thermal conductivity, such as aluminum or copper. The bonding layer 53 is formed of, for example, a bonding material having a high thermal conductivity, such as a nanosilver paste. The bonding layer 53 bonds a first surface 51a as a surface of the substrate 51, and the phosphor 52.

The phosphor 52 includes a rear surface 52a facing the substrate 51 and a front surface 52b opposite to the rear surface 52a. The phosphor 52 emits the fluorescence Y obtained by wavelength-conversion of the excitation light E incident from the front surface 52b from the front surface 52b.

The reflection layer 54 is provided to face the rear surface 52a of the phosphor 52 with the bonding layer 53 in between. That is, the reflection layer 54 is provided between the substrate 51 and the rear surface 52a of the phosphor 52. The reflection layer 54 is formed of a metal film such as silver having a high optical reflectance, a dielectric multilayer film, or a combination of these films. The reflection layer 54 reflects the fluorescence Y traveling toward an opposite side to the light incident side (the rear surface 52a side) within the phosphor 52 toward the light incident side (the front surface 52b side). The reflection layer 54 may reflect a part of the excitation light E to the light incident side (the front surface 52b side), and the excitation light E reflected by the reflection layer 54 is used to excite the fluorescence Y.

The wavelength conversion device 50 according to the embodiment functions as a reflective wavelength conversion device that emits the fluorescence Y from the front surface 52b of the phosphor 52 on which the excitation light E is incident.

It is generally known that when the temperature of the phosphor increases, the light emission efficiency of fluorescence decreases. In order to enhance the conversion efficiency of fluorescence in the phosphor, it is effective to enhance heat dissipation.

The inventors focused on enhancing the thermal conductivity of a phosphor by mixing and sintering of a YAG:Ce phosphor that is widely used as a phosphor and a high thermal conductive filler formed of AlN. In general, a sintered body of a phosphor including a phosphor phase formed of YAG:Ce and a matrix phase formed of AlN is formed by mixing and sintering of Al₂O₃ (alumina), Y₂O₃ (yttria), and CeO₂ (cerium oxide) which are raw-material powders and AlN powder which is a binder material.

However, when YAG:Ce and AlN are simply sintered, since the grain growth of AlN at sintering is earlier than the grain growth of YAG:Ce, YAG:Ce particles are hard to grow to a size that can emit a sufficient amount of light, the fluorescent emission efficiency becomes lower, and the extraction amount of fluorescence becomes smaller. That is, when the YAG:Ce and AlN are simply sintered, the internal quantum yield decreases and the extraction amount of fluorescence decreases. The internal quantum yield refers to a value (unit: %) obtained by division of the amount of fluorescence emitted by the phosphor by the absorption amount of the excitation light in the phosphor.

As a result of earnest studies, the inventors have found that a predetermined sintering additive is used for production of a fluorescence emission element including a sintered body containing a crystal phase formed of YAG:Ce and a matrix phase formed of AlN, and thereby, a predetermined amount of an oxide layer is formed at the boundary between the phosphor phase and the matrix phase and a phosphor having the enhanced thermal conductivity and internal quantum yield (extraction amount) of fluorescence can be manufactured. Then, the inventors accomplished the configuration of the phosphor 52 according to the embodiment.

Specifically, the phosphor 52 of the embodiment includes a phosphor body 520 including a phosphor phase 521, a matrix phase 522, and an oxide layer 523.

In the phosphor 52, the phosphor phase 521 contains phosphor particles formed of A₃B₅O₁₂:Ce having a garnet structure. In the phosphor phase 521 according to the embodiment, A is Y (yttrium) and B is AL (aluminum). That is, the phosphor phase 521 according to the embodiment contains phosphor particles formed of yttrium aluminum garnet (YAG (Y₃Al₅O₁₂):Ce) to which cerium (Ce) is added as an activator.

The matrix phase 522 is a transparent ceramic that functions as a binder for binding a plurality of phosphor particles forming the phosphor phase 521 and that transmits fluorescence emitted by the phosphor phase 521. The matrix phase 522 according to the embodiment is formed of aluminum nitride (AlN). The matrix phase 522 has a refractive index (2.2) higher than a refractive index of YAG:Ce (1.8) forming the phosphor phase 521.

A thermal conductivity of AlN forming the matrix phase 522 is about 285 W/m·K, and a thermal conductivity of YAG:Ce forming the phosphor phase 521 is about 9 W/m·K. That is, the matrix phase 522 has the thermal conductivity sufficiently higher than the thermal conductivity of the phosphor phase 521.

The thermal conductivity of the matrix phase 522 according to the embodiment is sufficiently higher than the thermal conductivity of Al₂O₃ (alumina) (about 30 W/m·K), which is generally used as a matrix phase of a ceramic phosphor. Therefore, the phosphor 52 according to the embodiment has excellent thermal conductivity and excellent heat dissipation as compared with a phosphor in the related art that uses Al₂O₃ as the matrix phase.

The phosphor 52 of the embodiment is manufactured, when YAG:Ce and AlN are sintered, by mixing and sintering of Al₂O₃, Y₂O₃, and CeO₂ as YAG raw-material powders and AlN powder with a predetermined sintering additive. Examples of the predetermined sintering additive include MgO (magnesium oxide) and CaO (calcium oxide), and MgO was used as the sintering additive in the phosphor 52 of the embodiment.

In the manufacturing process of the phosphor 52 of the embodiment, MgO is added as the sintering additive. MgO added as a sintering additive can relatively increase the growth rate of the grain size of YAG:Ce forming the phosphor phase 521 by suppressing the growth rate of the grain size of AlN forming the matrix phase 522. That is, the YAG: Ce particles forming the phosphor phase 521 can be grown to a grain size that enables sufficient fluorescence emission by adjustment of MgO so as to optimize the speed difference in grain growth between the matrix phase 522 and the phosphor phase 521.

Accordingly, the phosphor 52 of the embodiment has an excellent thermal conductivity and the extraction efficiency (internal quantum yield) of the fluorescence Y can be enhanced.

MgO added as a sintering additive during sintering of the phosphor 52 of the embodiment produces the oxide layer 523 between the phosphor phase 521 and the matrix phase 522. More specifically, the oxide layer 523 of the embodiment is provided at the boundary between the phosphor phase 521 and the matrix phase 522. The oxide layer 523 includes a composite oxide of a metal contained in the phosphor phase 521 and a metal contained in the sintering additive. That is, the oxide layer 523 is a by-product produced from the sintering additive. Specifically, the oxide layer 523 of the embodiment is formed of MgAl₂O₄. In FIG. 3, the oxide layer 523 is produced at all boundaries between the phosphor phases 521 and the matrix phases 522, and it is only necessary that the oxide layer 523 is produced at least at part of the boundaries.

The content of the oxide layer 523 is 0.1 vol % or more and 0.9 vol % or less in the volume ratio with respect to the phosphor body 520. According to the phosphor 52 in which the content of the oxide layer 523 is 0.1 vol % or more and 0.9 vol % or less, an appropriate amount of MgO that enables appropriate adjustment of the speed difference in grain growth between the matrix phase 522 and the phosphor phase 521 is added, and thereby, a higher thermal conductivity and a higher internal quantum yield are achieved.

Since the phosphor 52 of the embodiment includes the oxide layer 523, a light can be scattered at the interface between the oxide layer 523 and the phosphor phase 521 or at the interface between the oxide layer 523 and the matrix phase 522. Therefore, the phosphor 52 can successfully scatter a light inside the element, and thereby, the extraction efficiency (internal quantum yield) of the fluorescence Y can be enhanced.

FIG. 4 shows a main part configuration of the phosphor 52 according to the embodiment. FIG. 4 is an image obtained by imaging of the phosphor 52 using a SEM (scanning electron microscope).

As shown in FIG. 4, the phosphor body 520 of the phosphor 52 of the embodiment has the phosphor phase 521 and the matrix phase 522 which are uniformly dispersed. That is, it can be confirmed from the image of FIG. 4 that the phosphor 52 of the embodiment is a ceramic sintered body having a dense crystal structure. Since the oxide layer 523 produced at the boundary between the phosphor phase 521 and the matrix phase 522 does not appear in the image of FIG. 4, the oxide layer 523 is virtually illustrated in FIG. 4. Therefore, the oxide layer 523 shown in FIG. 4 is different from that in the actual state. The presence or absence of the oxide layer 523 can be determined, for example, by using an X-ray diffraction method (XRD).

As described above, the phosphor 52 of the embodiment includes the phosphor body 520 including the phosphor phase 521 formed of YAG (Y₃Al₅O₁₂):Ce having the garnet structure, the matrix phase 522 formed of AlN having the refractive index higher than the refractive index of the phosphor phase 521, and the oxide layer 523 provided between the phosphor phase 521 and the matrix phase 522. The oxide layer 523 includes the composite oxide of the metal contained in the phosphor phase 521 and the metal contained in MgO as the sintering additive. The content of the oxide layer 523 is 0.1 vol % or more and 0.9 vol % or less in the volume ratio with respect to the phosphor body 520.

According to the phosphor 52 of the embodiment, since the content of the oxide layer 523 contained in the phosphor body 520 is 0.1 vol % or more and 0.9 vol % or less, the phosphor is sintered with an appropriate amount of MgO as a sintering additive. Therefore, the respective phases can be grown with good balance by adjustment of the speed difference in grain growth between the matrix phase 522 and the phosphor phase 521. Accordingly, YAG:Ce particles forming the phosphor phase 521 grow to the particle size that enables sufficient fluorescence emission, and therefore, the phosphor 52 of the embodiment has the excellent thermal conductivity and the extraction efficiency (internal quantum yield) of the fluorescence Y can be improved.

In addition, since the phosphor 52 of the embodiment includes the matrix phase 522 formed of AlN having the high thermal conductivity, a decrease in fluorescence conversion efficiency due to a temperature rise can be suppressed by efficient release of heat caused by fluorescence emission. As a result, the excitation light E is efficiently absorbed by the phosphor phase 521 and the light emission efficiency of the fluorescence Y is enhanced, and thereby, the bright fluorescence Y can be generated.

According to the phosphor 52 of the embodiment, the internal quantum yield of the fluorescence Y is increased to 85% or more, and thereby, the fluorescence Y having the brightness that is acceptable in practical use as the illumination light for the projector can be emitted from the phosphor 52.

The wavelength conversion device 50 according to the embodiment includes the substrate 51, the phosphor 52 that is provided on the substrate 51 and converts the incident excitation light E into the fluorescence, and the reflection layer 54 that is provided at the opposite side to the light incident side of the phosphor 52.

According to the wavelength conversion device 50 of the embodiment, the reflective wavelength conversion device that efficiently extracts the bright fluorescence Y can be provided.

The illumination device 2 according to the embodiment includes the first light source 40 that emits the excitation light E and the wavelength conversion device 50 on which the excitation light E is incident.

According to the illumination device 2 of the embodiment, the illumination device that has excellent wavelength conversion efficiency and emits the bright illumination light WL can be provided.

The projector 1 according to the embodiment includes the illumination device 2, the light modulators 4R, 4G, and 4B that modulate the light emitted from the illumination device 2, and the projection optical device 6 that projects the light modulated by the light modulators 4R, 4G, and 4B.

According to the projector 1 of the embodiment, the projector having excellent display quality and high efficiency can be provided.

### Second Embodiment

Hereinafter, a projector according to a second embodiment will be described.

A basic configuration of the projector according to the second embodiment is the same as that of the first embodiment, and a configuration of the illumination device is different from that of the first embodiment. Therefore, the configuration of the illumination device will be described below.

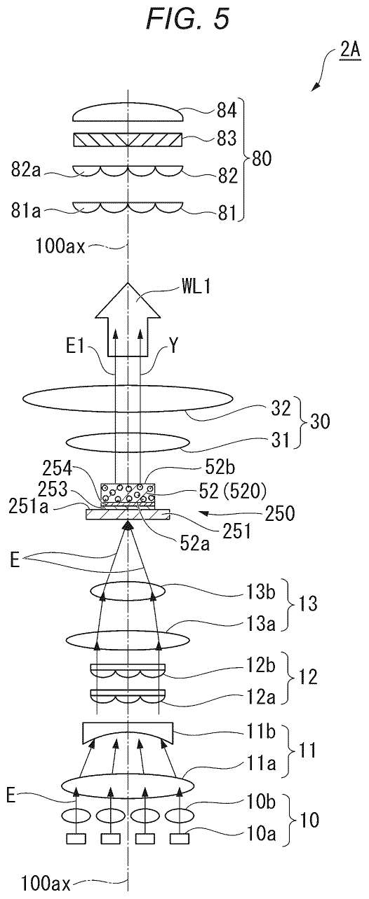

FIG. 5 is a schematic configuration diagram showing an illumination device 2A according to the second embodiment.

In FIG. 5, component elements common to those in the drawings used in the above embodiment have the same signs, and a description thereof is omitted.

As shown in FIG. 5, the illumination device 2A includes an excitation light source unit 10, an afocal system 11, a homogenizer system 12, a condensing system 13, a wavelength conversion device 250, a pickup system 30, and the uniform illumination system 80.

The excitation light source unit 10 includes a plurality of semiconductor lasers 10a that emit the blue excitation lights E as laser beams, and a plurality of collimator lenses 10b. The plurality of semiconductor lasers 10a are arranged in an array manner in a plane orthogonal to the illumination optical axis 100ax. The collimator lenses 10b are arranged in an array manner in the plane orthogonal to the illumination optical axis 100ax so as to correspond to the respective semiconductor lasers 10a. The collimator lens 10b converts the excitation light E emitted from the semiconductor laser 10a corresponding to the collimator lens 10b into a parallel light.

The excitation light source unit 10 according to the embodiment corresponds to “light source” in the claims.

The afocal system 11 includes, for example, a convex lens 11a and a concave lens 11b. The afocal system 11 reduces a luminous flux diameter of the excitation light E including a parallel luminous flux emitted from the excitation light source unit 10.

The homogenizer system 12 includes, for example, a first multi-lens array 12a and a second multi-lens array 12b. The homogenizer system 12 makes a light intensity distribution of the excitation light uniform on the phosphor 52 of the wavelength conversion device 250, that is, a so-called top hat distribution. The homogenizer system 12, together with the condensing system 13, superimposes a plurality of small luminous fluxes emitted from a plurality of lenses of the first multi-lens array 12a and the second multi-lens array 12b on the phosphor 52 of the wavelength conversion device 250. Accordingly, the light intensity distribution of the excitation light E emitted to the phosphor 52 is made uniform.

The condensing system 13 includes, for example, a first lens 13a and a second lens 13b. In the embodiment, each of the first lens 13a and the second lens 13b is formed using a convex lens. The condensing system 13 is disposed in an optical path from the homogenizer system 12 to the wavelength conversion device 250, condenses the excitation light E, and causes the excitation light E to enter the phosphor 52 of the wavelength conversion device 250.

The wavelength conversion device 250 according to the embodiment includes a substrate 251, the phosphor 52, a bonding layer 253, and an optical layer 254. The wavelength conversion device 250 according to the embodiment is a fixed-type wavelength conversion device in which an incident position of the excitation light E on the phosphor 52 does not change over time.

The substrate 251 supports the optical layer 254 and the phosphor 52 through the bonding layer 253. The substrate 251 is formed of, for example, a transparent material such as a glass or a plastic. The bonding layer 253 according to the embodiment is formed of, for example, a material having optical transparency, such as epoxy. The bonding layer 253 bonds a first surface 251a, which is a front surface of the substrate 251, and the phosphor 52.

In the phosphor 52 according to the embodiment, the excitation light E enters from the rear surface 52a facing the substrate 251, and the fluorescence Y is emitted from the front surface 52b. In the wavelength conversion device 250 according to the embodiment, the phosphor 52 transmits and emits not only the fluorescence Y but also a part of an excitation light E1 whose wavelength is not converted. Accordingly, a white illumination light WL1 is emitted from the phosphor 52.

The optical layer 254 is provided on the rear surface 52a at the light incident side of the phosphor 52. The optical layer 254 includes a dichroic mirror that transmits the excitation light E and reflects the fluorescence Y.

The wavelength conversion device 250 according to the embodiment functions as a transmissive wavelength conversion device that emits the illumination light WL1 containing the fluorescence Y from the front surface 52b opposite to the rear surface 52a of the phosphor 52 on which the excitation light E is incident.

The pickup system 30 includes, for example, a first collimating lens 31 and a second collimating lens 32. The pickup system 30 is a parallelizing system for substantially parallelizing the light emitted from the phosphor 52 of the wavelength conversion device 250. Each of the first collimating lens 31 and the second collimating lens 32 is formed using a convex lens. The light parallelized by the pickup system 30 is incident on the uniform illumination system 80.

### Effects of Second Embodiment

According to the embodiment, the transmissive wavelength conversion device 250 that generates the bright fluorescence Y may be realized by using the phosphor 52 that can increase an amount of extracted fluorescence Y. In addition, in the illumination device 2A according to the embodiment as well, the transmissive wavelength conversion device 250 is provided, and thereby, the effect same as that of the first embodiment in which the wavelength conversion efficiency is excellent and the bright illumination light WL1 can be emitted can be obtained.

The technical scope of the present disclosure is not limited to the above embodiments, and various modifications can be made without departing from the gist of the present disclosure.

Specific descriptions of shapes, numbers, arrangements, materials, manufacturing methods, and the like of the respective component elements of the phosphor, the wavelength conversion device, the illumination device, and the projector described in the above embodiments are not limited to those of the above embodiments, and can be appropriately changed.

In the above embodiments, YAG containing Ce is taken as an example of the phosphor phase 521, and the present disclosure is also applicable to a case of using a phosphor phase containing Ce in at least one of Lu₃Al₅O₁₂, Tb₃Al₅O₁₂, Ga₃Al₅O₁₂, and Gd₃Al₅O₁₂. That is, in addition to the case of using Y (yttrium), the present disclosure is also applicable to a case in which A in the garnet structure (A₃B₅O₁₂:Ce) is replaced with any of Lu (lutetium), Gd (gallium), Tb (terbium), and Ga (gallium) providing emission characteristics similar to those of Y.

In the above embodiment, AlN is taken as an example of the matrix phase 522. Alternatively, SiC or BN may be used.

In the above embodiment, the case where MgO is used as the sintering additive is taken as an example. CaO may be used as the sintering additive in place of MgO. When CaO is used as the sintering additive, the oxide layer including a composite oxide of the metal contained in the phosphor phase and the metal contained in the sintering additive is formed of CaAl₂O₄.

Hereinafter, a summary of the disclosure will be appended.

### Appendix 1

A phosphor includes a phosphor body including a phosphor phase formed of A₃B₅O₁₂:Ce having a garnet structure, a matrix phase having a refractive index higher than a refractive index of the phosphor phase, and an oxide layer provided between the phosphor phase and the matrix phase, wherein the oxide layer includes a composite oxide of a metal contained in the phosphor phase and a metal contained in the sintering additive, and a content of the oxide layer is 0.1 vol % or more and 0.9 vol % or less in a volume ratio with respect to the phosphor body.

A is at least one selected from a group including Lu, Gd, Tb, Ga, and Y, and B is Al.

According to the phosphor having the configuration, the content of the oxide layer contained in the phosphor body is 0.1 vol % or more and 0.9 vol % or less. Therefore, the phosphor is sintered with the appropriate amount of the sintering additive. Accordingly, the speed difference in grain growth between the matrix phase and the phosphor phase is adjusted, and the respective phases can be grown with good balance. In addition, since the phosphor phase grows to a particle size that enables sufficient fluorescence emission, the thermal conductivity is excellent and the fluorescence extraction efficiency can be improved.

Therefore, the phosphor having the configuration can efficiently generate bright fluorescence.

### Appendix 2

In the phosphor according to Appendix 1, A is Y.

According to the configuration, the phosphor that efficiently generates bright fluorescence containing the phosphor phase formed of YAG (Y₃Al₅O₁₂):Ce can be realized.

### Appendix 3

In the phosphor according to Appendix 1 or Appendix 2, the matrix phase is AlN.

According to the configuration, since the phosphor includes the matrix phase formed of AlN having a high thermal conductivity, a decrease in fluorescence conversion efficiency due to a temperature rise can be suppressed by efficient release of heat caused by fluorescence emission.

### Appendix 4

In the phosphor according to any one of Appendix 1 to Appendix 3, the oxide layer is MgAl₂O₄.

According to the configuration, the phosphor body containing a predetermined amount of MgAl₂O₄ as the oxide layer is provided, and thereby, the fluorescent emission element that efficiently generates bright fluorescence can be realized when MgO is used as the sintering additive.

### Appendix 5

In the phosphor according to any one of Appendix 1 to Appendix 3, the oxide layer is CaAl₂O₄.

According to the configuration, the phosphor body containing a predetermined amount of CaAl₂O₄ as the oxide layer is provided, and thereby, the fluorescent emission element that efficiently generates bright fluorescence can be realized when CaO is used as the sintering additive.

### Appendix 6

A wavelength conversion device includes a substrate, the phosphor according to any one of Appendix 1 to Appendix 5 provided on the substrate and converting an incident excitation light into fluorescence, and a reflection layer provided at an opposite side to a light incident side of the phosphor.

According to the wavelength conversion device having the configuration, the reflective wavelength conversion device that efficiently extracts bright fluorescence Y can be provided.

### Appendix 7

A wavelength conversion device includes a substrate, the phosphor according to any one of Appendix 1 to Appendix 5 provided on the substrate and converting an incident excitation light into fluorescence, and an optical layer provided on a light incident side of the phosphor and transmitting the excitation light and reflecting the fluorescence.

According to the wavelength conversion device having the configuration, the transmissive wavelength conversion device that efficiently extracts bright fluorescence can be provided.

### Appendix 8

An illumination device includes a light source emitting the excitation light, and the wavelength conversion device according to Appendix 6 or Appendix 7, on which the excitation light is incident.

According to the illumination device having the configuration, the illumination device that has excellent wavelength conversion efficiency and emits a bright illumination light can be provided.

### Appendix 9

A projector includes the illumination device according to Appendix 8, a light modulator modulating a light emitted from the illumination device, and a projection optical device projecting the light modulated by the light modulator.

According to the projector having the configuration, the projector having excellent display quality and high efficiency can be provided.

### EXAMPLES

Hereinafter, the present disclosure will be described in more detail with reference to Examples, and the present disclosure is not limited to Examples.

### Example 1

As Example 1, a phosphor is prepared by sintering of YAG:Ce and AlN with MgO at 0.25 wt % as a sintering additive for setting the content of MgAl₂O₄ as an oxide layer to 0.10%.

### Example 2

As Example 2, a phosphor is prepared by sintering of YAG:Ce and AlN with MgO at 0.50 wt % as a sintering additive for setting the content of MgAl₂O₄ as an oxide layer to 0.10%.

### Example 3

As Example 3, a phosphor is prepared by sintering of YAG:Ce and AlN with MgO at 0.75 wt % as a sintering additive for setting the content of MgAl₂O₄ as an oxide layer to 0.15%.

### Example 4

As Example 4, a phosphor is prepared by sintering of YAG:Ce and AlN with MgO at 1.00 wt % as a sintering additive for setting the content of MgAl₂O₄ as an oxide layer to 0.40%.

### Example 5

As Example 5, a phosphor is prepared by sintering of YAG:Ce and AlN with MgO at 1.50 wt % as a sintering additive for setting the content of MgAl₂O₄ as an oxide layer to 0.90%.

### Comparative Example 1

As Comparative Example 1, a phosphor is prepared by sintering of YAG:Ce and AlN without MgO (content: 0 wt %) as a sintering additive.

### Comparative Example 2

As Comparative Example 2, a phosphor is prepared by sintering of YAG:Ce and AlN with MgO at 0.10 wt % as a sintering additive for setting the content of MgAl₂O₄ as an oxide layer to 0.05%.

### Comparative Example 3

As Comparative Example 3, a phosphor is prepared by sintering of YAG:Ce and AlN with MgO at 2.00 wt % as a sintering additive for setting the content of MgAl₂O₄ as an oxide layer to 1.30%.

### Comparative Example 4

As Comparative Example 4, a phosphor is prepared by sintering of YAG:Ce and AlN with MgO at 5.00 wt % as a sintering additive for setting the content of MgAl₂O₄ as an oxide layer to 3.005%.

### Evaluation of Examples and Comparative Examples

In each of Examples and Comparative Examples described above, the thermal conductivity (unit: W/m·K) and the internal quantum yield (unit: %) were checked, and a phosphor having a higher internal quantum yield and a higher thermal conductivity was determined as a phosphor having higher light utilization efficiency. Determination results are shown in Table 1. The content of MgAl₂O₄ as the oxide layer was measured by X-ray diffraction (XRD). The thermal conductivity is a value based on the measurement result at room temperature.

In Table 1, samples with thermal conductivities at 20% or more were evaluated as A (acceptable), and samples with thermal conductivities at less than 20% were evaluated as B (unacceptable). In addition, in Table 1, samples with internal quantum yields at 85% or more were evaluated as A (acceptable), and samples with internal quantum yields at less than 85% were evaluated as B (unacceptable).

Further, as overall evaluations, samples whose evaluation items of the thermal conductivity and the internal quantum yield were both A were rated A (acceptable), and samples whose evaluation item of at least one of the thermal conductivity and the internal quantum yield was B were rated B (unacceptable).

TABLE 1

| | Amount of | MgAl₂O₄ | Thermal | Internal |
|---|---|---|---|---|
| | sintering | content | conductivity | quantum |
| | additive (wt %) | (vol %) | (W/m · K) | yield (%) |
| Comparative | 0 | 0 | 14.3 | 66.6 |
| Example 1 | | | | |
| Comparative | 0.10 | 0.05 | 29.4 | 72.6 |
| Example 2 | | | | |
| Example 1 | 0.25 | 0.10 | 35.1 | 87.2 |
| Example 2 | 0.50 | 0.10 | 40.7 | 87.4 |
| Example 3 | 0.75 | 0.15 | 41.4 | 89.1 |
| Example 4 | 1.00 | 0.40 | 46.1 | 86.5 |
| Example 5 | 1.50 | 0.90 | 42.8 | 86.1 |
| Comparative | 2.00 | 1.30 | 40.1 | 83.6 |
| Example 3 | | | | |
| Comparative | 5.00 | 3.00 | 19.7 | 70.4 |
| Example 4 | | | | |

| | Evaluation | Evaluation | |
|---|---|---|---|
| | of thermal | of internal | |
| | conductivity | quantum yield | Determination |
| Comparative | B | B | B |
| Example 1 | | | |
| Comparative | A | B | B |
| Example 2 | | | |
| Example 1 | A | A | A |
| Example 2 | A | A | A |
| Example 3 | A | A | A |
| Example 4 | A | A | A |
| Example 5 | A | A | A |
| Comparative | A | B | B |
| Example 3 | | | |
| Comparative | B | B | B |
| Example 4 | | | |

A: 20 or more
A: 85 or more
A: acceptable
B: less than 20
B: less than 85
B: unacceptable

As shown in Table 1, in Comparative Example 1 (MgAl₂O₄ content: 0 vol %), YAG:Ce particles were harder to grow than AlN particles, and the amount of YAG:Ce particles contributing to light emission was smaller. On the other hand, since AlN was easier to grow than YAG:Ce, defects in the interface between AlN and YAG:Ce also increased, and both the thermal conductivity and the internal quantum yield took lower values as 14.3 and 66.6%, respectively. Further, in Comparative Example 2 (MgAl₂O₄ content: 0.05 vol %), the thermal conductivity was improved to 29.4 by suppression of defects in the interface between AlN and YAG:Ce compared to Comparative Example 1, however, the amount of YAG:Ce particles was not sufficient and the internal quantum yield is as low as 72.6%.

On the other hand, in Example 1 (MgAl₂O₄ content: 0.10 vol %), Example 2 (MgAl₂O₄ content: 0.10 vol %), Example 3 (MgAl₂O₄ content: 0.15 vol %), Example 4 (MgAl₂O₄ content: 0.40 vol %), and Example 5 (MgAl₂O₄ content: 0.90 vol %), it was confirmed that all of the thermal conductivities and the internal quantum yields took higher values as 35.1, 40.7, 41.4, 46.1, 42.8 and 87.2%, 87.4%, 89.1%, 86.5%, 86.1%, respectively.

That is, it was confirmed that when the content of MgAl₂O₄ as the oxide layer is 0.1 vol % or more and 0.9 vol % or less as in Examples 1 to 5, a fluorescence emission element having a thermal conductivity of 20 or more and an internal quantum yield of 55% or more can be obtained.

On the other hand, in Comparative Example 3 (MgAl₂O₄ content: 1.30 vol %), a sufficient value of 40.1 is obtained as the thermal conductivity, but the growth balance between AlN and YAG:Ce is deteriorated and the internal quantum yield is decreased to 83.6%.

In addition, in Comparative Example 4 (MgAl₂O₄ content: 3.00 vol %) in which the MgO content is higher than that in Comparative Example 3, the production amount of MgAl₂O₄ is excessively increased, the growth balance between AlN and YAG:Ce is further deteriorated, the optical loss in the phosphor is increased, and thereby, the thermal conductivity is decreased to 19.7 and the internal quantum yield is decreased to 70.4%.

That is, it was confirmed that when the MgAl₂O₄ content is higher than 0.9 vol % as in Comparative Examples 3 and 4, both the thermal conductivity and the fluorescent emission efficiency decrease.

Based on the above results, according to the phosphors in Examples 1 to 5, it is confirmed that the thermal conductivity and the internal quantum yield are enhanced in a balanced manner by setting the MgAl₂O₄ content to 0.1 vol % or more and 0.9 vol % or less to enhance the fluorescence emission efficiency, and thereby, bright fluorescence can be generated.

What is claimed is:

1. A phosphor comprising a phosphor body including:
a phosphor phase formed of A₃B₅O₁₂:Ce having a garnet structure,
a matrix phase having a refractive index higher than a refractive index of the phosphor phase, and
an oxide layer provided between the phosphor phase and the matrix phase, wherein
the oxide layer includes a composite oxide of a metal contained in the phosphor phase and a metal contained in the sintering additive, and
a content of the oxide layer is equal to or more than 0.1 vol % and is equal to or less than 0.9 vol % in a volume ratio with respect to the phosphor body,
A is at least one selected from a group including Lu, Gd, Tb, Ga, and Y, and B is Al.

2. The phosphor according to claim 1, wherein
A is Y.

3. The phosphor according to claim 1, wherein
the matrix phase is AlN.

4. The phosphor according to claim 1, wherein
the oxide layer is MgAl₂O₄.

5. The phosphor according to claim 1, wherein
the oxide layer is CaAl₂O₄.

6. A wavelength conversion device comprising:
a substrate;
the phosphor according to claim 1 provided on the substrate and configured to convert an incident excitation light into fluorescence; and
a reflection layer provided at an opposite side to a light incident side of the phosphor.

7. A wavelength conversion device comprising:
a substrate;
the phosphor according to claim 1 provided on the substrate and configured to convert an incident excitation light into fluorescence; and
an optical layer provided on a light incident side of the phosphor and configured to transmit the excitation light and reflect the fluorescence.

8. An illumination device comprising:
a light source emitting the excitation light; and
the wavelength conversion device according to claim 6, on which the excitation light is incident.

9. An illumination device comprising:
a light source emitting the excitation light; and
the wavelength conversion device according to claim 7, on which the excitation light is incident.

10. A projector comprising:
the illumination device according to claim 8;
a light modulator modulating a light emitted from the illumination device; and
a projection optical device projecting the light modulated by the light modulator.

11. A projector comprising:
the illumination device according to claim 9;
a light modulator modulating a light emitted from the illumination device; and
a projection optical device projecting the light modulated by the light modulator.
